(19) United States
(12) Patent Application Publication
(10) Pub. No.: US 2026/0293504 A1
(43) Pub. Date: Sep. 24, 2026

(54) DISPLAY DEVICE

(71) Applicant: Samsung Display Co., LTD., Yongin-si (KR)

(72) Inventors: Hee Sung LIM, Yongin-si (KR); Young Moo KWON, Yongin-si (KR); Young Kwan KIM, Yongin-si (KR); Young Dae SONG, Yongin-si (KR); Hyo Seok YANG, Yongin-si (KR)

(21) Appl. No.: 19/386,623

(22) Filed: Nov. 12, 2025

(30) Foreign Application Priority Data
Mar. 21, 2025 (KR) 10-2025-0036453

(51) Int. Cl. H10K 59/80

(52) U.S. Cl. CPC H10K 59/8792; H10K 59/873

(57) ABSTRACT

A display device includes a display panel; and a cover panel positioned on one surface of the display panel, where the cover panel includes: a light blocking layer positioned on the one surface of the display panel, a cushion layer positioned on the light blocking layer, a first metal layer positioned on the cushion layer, and a second metal layer positioned on the first metal layer. In a plan view, the cover panel includes a central area, peripheral areas adjacent to the central area in a first direction and a second direction intersecting the first direction, and corner areas at least partially surrounding the central area and the peripheral areas, the first metal layer defines therein through-holes, which overlap the corner areas and penetrate through the first metal layer, and the through-holes are spaced apart from each other.

This application claims priority to Korean Patent Application No. 10-2025-0036453, filed on Mar. 21, 2025, and all the benefits accruing therefrom under 35 U.S.C. §119, the content of which in its entirety is herein incorporated by reference.

### BACKGROUND

### Technical Field

The present disclosure relates to a display device.

### Description of the Related Art

The importance of a display device is increasing with the development of multimedia. Accordingly, various types of display devices such as an organic light emitting display (OLED) and a liquid crystal display (LCD) are being used.

The display device includes a display panel such as an organic light emitting display panel or a liquid crystal display panel as a device for displaying an image of the display device. An example of the light emitting display panel among the display panels may include a light emitting element such as a light emitting diode (LED), and examples of such a light emitting diode include an organic light emitting diode (OLED) that uses an organic material as a fluorescent material, an inorganic light emitting diode that uses an inorganic material as a fluorescent material, and the like.

In addition, the display device includes a panel lower member disposed below the display panel. The panel lower member may include various functional sheets for protecting the display panel from heat, external impact, etc.

### SUMMARY

Aspects of the present disclosure provide a display device capable of preventing a lifting phenomenon of a cover panel disposed below a display panel that occurs under high temperature and high humidity conditions.

It should be noted that objects of the present disclosure are not limited to the above-mentioned object; and other objects of the present disclosure will be apparent to those skilled in the art from the following descriptions.

According to an aspect of the present disclosure, a display device includes a display panel; and a cover panel positioned on one surface of the display panel, where the cover panel includes: a light blocking layer positioned on the one surface of the display panel, a cushion layer positioned on the light blocking layer, a first metal layer positioned on the cushion layer, and a second metal layer positioned on the first metal layer. In a plan view, the cover panel includes a central area, peripheral areas adjacent to the central area in a first direction and a second direction intersecting the first direction, and corner areas at least partially surrounding the central area and the peripheral areas, the first metal layer defines therein through-holes that overlap the corner areas and penetrate through the first metal layer, and the through-holes being spaced apart from each other.

In an embodiment, the outermost edges of the corner areas of the cover panel may include a curve in the plan view.

In an embodiment, the through-holes may be arranged in a radial pattern.

In an embodiment, the through-holes may not be visually recognized from the outside of the cover panel.

In an embodiment, the coefficient of thermal expansion of the first metal layer and the coefficient of thermal expansion of the second metal layer may be different from each other.

In an embodiment, the coefficient of thermal expansion of the first metal layer may be greater than the coefficient of thermal expansion of the second metal layer.

In an embodiment, the display device may further include an adhesive layer positioned between the cushion layer and the first metal layer, and the adhesive layer may be further positioned inside the through-holes.

In an embodiment, the adhesive layer may be in direct contact with inner side surfaces of the first metal layer defining the through-holes.

In an embodiment, the display device may further include a lower adhesive layer positioned between the first metal layer and the second metal layer, and the lower adhesive layer may be further positioned inside the through-holes.

In an embodiment, the lower adhesive layer may be in direct contact with inner side surfaces of the first metal layer defining the through-holes.

In an embodiment, the first metal layer may include aluminum, and the second metal layer includes copper.

According to an aspect of the present disclosure, a display device includes a display panel; and a cover panel positioned on one surface of the display panel, wherein the cover panel includes: a light blocking layer positioned on the one surface of the display panel, a cushion layer positioned on the light blocking layer, a first metal layer positioned on the cushion layer, and a second metal layer positioned on the first metal layer. In a plan view, the cover panel includes a central area, peripheral areas adjacent to the central area in a first direction and a second direction intersecting the first direction, and corner areas at least partially surrounding the central area and the peripheral areas, the first metal layer defines therein through-holes that overlap the central area and the peripheral areas and penetrate through the first metal layer, and the through-holes are spaced apart from each other.

In an embodiment, the outermost edges of the corner areas of the cover panel may include a curve in the plan view.

In an embodiment, the coefficient of thermal expansion of the first metal layer and the coefficient of thermal expansion of the second metal layer may be different from each other.

In an embodiment, the coefficient of thermal expansion of the first metal layer may be greater than the coefficient of thermal expansion of the second metal layer.

In an embodiment, the display device may further include an adhesive layer positioned between the cushion layer and the first metal layer, and the adhesive layer may be further positioned inside the through-holes.

In an embodiment, the adhesive layer may be in direct contact with inner side surfaces of the first metal layer defining the through-holes.

In an embodiment, the display device may further include a lower adhesive layer positioned between the first metal layer and the second metal layer, and the lower adhesive layer may be further positioned inside the through-holes.

In an embodiment, the lower adhesive layer may be in direct contact with inner side surfaces of the first metal layer defining the through-holes.

According to an aspect of the present disclosure, an electronic device includes a display device for displaying an image and a processor for transmitting an image data signal for displaying the image to the display device, where the display device includes: a display panel; and a cover panel positioned on one surface of the display panel. The cover panel includes: a light blocking layer positioned on the one surface of the display panel, a cushion layer positioned on the light blocking layer, a first metal layer positioned on the cushion layer, and a second metal layer positioned on the first metal layer. In a plan view, the cover panel includes a central area, peripheral areas adjacent to the central area in a first direction and a second direction intersecting the first direction, and corner areas at least partially surrounding the central area and the peripheral areas, the first metal layer defines therein through-holes that overlap the corner areas and penetrate through the first metal layer, and the through-holes are spaced apart from each other.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to embodiments of the present disclosure, the lifting phenomenon of the cover panel disposed below the display panel that occurs under the high temperature and high humidity conditions may be prevented, and accordingly, the display device having improved reliability may be provided.

It should be noted that the effects of the present disclosure are not limited to those described above, and other effects not mentioned will be clearly understood by those skilled in the art from the description below.

### BRIEF DESCRIPTION OF THE DRAWINGS

The above and other aspects and features of the present disclosure will become more apparent by describing in detail embodiments thereof with reference to the attached drawings, in which:

FIG. 1 is an exploded perspective view of a display device according to an embodiment;

FIG. 2 is a rear view of the display device according to an embodiment;

FIG. 3 is an enlarged plan view of portion B1 of FIG. 2;

FIG. 4 is a cross-sectional view of the display device of FIG. 3 taken along line X1-X1’;

FIG. 5 is an enlarged cross-sectional view of a portion B3 of FIG. 4;

FIGS. 6 to 8 are views illustrating modified examples of the display device of FIG. 5;

FIG. 9 is a cross-sectional view taken along line X1-X1’ of FIG. 3 of a display device according to another embodiment;

FIG. 10 is an enlarged cross-sectional view of portion B5 of FIG. 9;

FIGS. 11 to 13 are views illustrating modified examples of the display device of FIG. 10;

FIG. 14 is a rear view of a display device according to another embodiment;

FIG. 15 is an enlarged plan view of portion B7 of FIG. 14;

FIG. 16 is a block diagram of an electronic device according to an embodiment; and

FIG. 17 illustrates a schematic diagram of electronic devices according to various embodiments.

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being "on" another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Hereinafter, embodiments of the present disclosure will be described in detail with reference to the accompanying drawings.

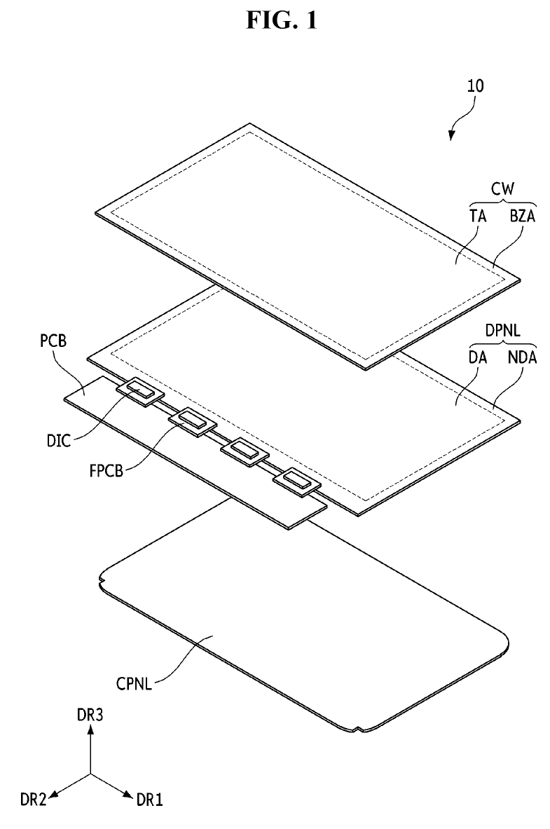

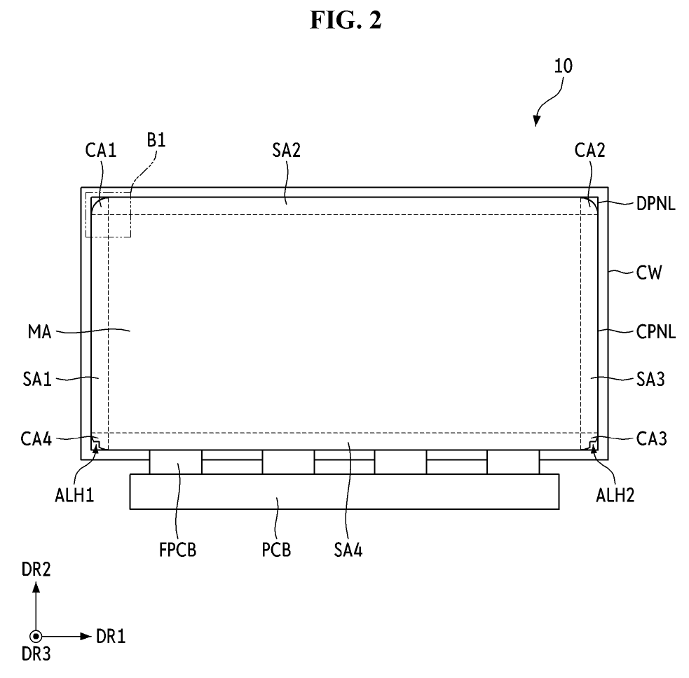

FIG. 1 is an exploded perspective view of a display device according to an embodiment. FIG. 2 is a rear view of the display device according to an embodiment.

Referring to FIGS. 1 and 2, a display device 10 is a device that displays a moving image or still image and may be used as a display screen for various products.

The display device 10 may be a light emitting display device such as an organic light emitting display device including an organic light emitting diode, a quantum dot light emitting display device including a quantum dot light emitting layer, an inorganic light emitting display device including an inorganic semiconductor, and an ultra-small light emitting display device including an ultra-small light emitting diode such as a micro or nano light emitting diode (micro LED or nano LED), but is not limited thereto. For example, the display device 10 may be a type of display device other than the light emitting display device. Hereinafter, embodiments in which the display device 10 is a light emitting display device (e.g., an organic light emitting display device) are disclosed.

A shape of the display device 10 may be variously changed. For example, the display device 10 may have a shape such as a rectangle with a long length, a rectangle with a long width, a square, a quadrangle with rounded corners (vertices), other polygons, or a circle. In FIGS. 1 and 2, a display device 10 having a rectangular shape with a long length in a first direction DR1 is illustrated.

In the present specification, a first direction DR1 may be a direction parallel to a long side of the display device 10 in a plan view, for example, a horizontal direction of the display device 10. A second direction DR2 may be a direction parallel to a short side of the display device 10 in a plan view, for example, a vertical direction of the display device 10. A third direction DR3 may be a thickness direction of the display device 10.

The display device 10 may include a display panel DPNL, a cover window CW disposed above the display panel DPNL, and a cover panel CPNL disposed below the display panel DPNL.

The display panel DPNL may include a display area DA that displays an image and a non-display area NDA disposed around the display area DA.

A plurality of pixels may be disposed in the display area DA. The pixels may display an image. Each of the pixels may include a pixel driving circuit including

transistors (e.g., a switching transistor, a driving transistor, etc.) and at least one capacitor, and a light emitting element electrically connected to the pixel driving circuit. The pixels may generate light in response to an electrical signal applied to each pixel, and display an image through the display area DA. According to an embodiment, some of the pixels may include transistors disposed in the non-display area NDA, but the present disclosure is not limited to either.

The non-display area NDA may be an area that does not display an image. The non-display area NDA may be an edge area of the display panel DPNL. The non-display area NDA may be an area outside the display area DA and may be disposed to surround the display area DA. A pad portion (not illustrated) for connection to a flexible circuit board FPCB may be provided at one edge of the non-display area NDA, and flexible circuit boards FPCB may be connected to the pad portion.

The cover window CW may be disposed on the display panel DPNL to protect the display panel DPNL. The cover window CW may be disposed to overlap the display panel DPNL and cover a front surface of the display panel DPNL. The cover window CW may be larger than the display panel DPNL. The cover window CW may include a material including glass, sapphire, plastic, or the like. The cover window CW may be rigid, but is not limited thereto, and may also be flexible.

The cover window CW may include a transmission area TA that transmits the image provided by the display panel DPNL and a bezel area BZA adjacent to the transmission area TA. The transmission area TA may be an area in which the image is displayed. In the present embodiment, the transmission area TA is illustrated as a rectangular shape having a long width, but this is only an example, and the transmission area TA may have various shapes and is not limited to any one embodiment. The bezel area BZA may surround and be adjacent to the transmission area TA. Accordingly, the shape of the transmission area TA may be substantially defined by the bezel area BZA. However, this is illustrated by way of example, and the bezel area BZA may also be disposed adjacent to only one side of the transmission area TA or may also be omitted.

The cover panel CPNL may be disposed below the display panel DPNL to support and protect the display panel DPNL.

As illustrated in FIG. 2, the cover panel CPNL may include a central area MA, peripheral areas SA1, SA2, SA3, and SA4 adjacent to the central area MA in the first direction DR1 and the second direction DR2 intersecting the first direction DR1, and corner areas CA1, CA2, CA3, and CA4 surrounding at least some of the central area MA and peripheral areas SA1, SA2, SA3, and SA4 in a plan view.

The outermost edges of the corner areas CA1, CA2, CA3, and CA4 may include curves. For example, the outermost edges of the corner areas CA1, CA2, CA3, and CA4 of the cover panel CPNL may each have a round shape. As the outermost edges of the corner areas CA1, CA2, CA3, and CA4 of the cover panel CPNL include the curves, it is possible to disperse a force generated inside the cover panel CPNL due to thermal expansion, etc. and concentrated at the corners. Therefore, a lifting phenomenon of the cover panel CPNL due to thermal expansion that occurs under high temperature and high humidity conditions may be prevented, and thus the reliability of the display device 10 may be improved.

In addition, the corner area CA may define therein an alignment opening ALH positioned at the outermost edge of the cover panel CPNL. It is illustrated in FIG. 2 that a first alignment opening ALH1 and a second alignment opening ALH2 positioned at a third corner area CA3 and a fourth corner area CA4, respectively, are illustrated, but this is illustrated as an example, and the alignment opening ALH may be positioned at one or more of the first to fourth corner areas CA1, CA2, CA3, and CA4, and the present disclosure is not limited to any one embodiment.

The display device 10 may further include flexible circuit boards FPCB, driving circuits DIC, and a circuit board PCB.

Each of the flexible circuit boards FPCB may be disposed on the pad portion disposed on one edge of the display panel DPNL. Each of the flexible circuit boards FPCB may be attached to the pad portion using a conductive adhesive member such as an anisotropic conductive film. Due to this, a plurality of flexible circuit boards FPCB may be electrically connected to signal lines of the display panel DPNL. The plurality of flexible circuit boards FPCB may be a flexible film such as a flexible printed circuit board or a chip on film.

Each of the driving circuits DIC may be formed as an integrated circuit (IC) and attached to a corresponding flexible circuit board FPCB, but the embodiment of the present specification is not limited thereto. Each of the driving circuits DIC may also be attached onto the display panel DPNL by a chip on glass (COG) method, a chip on plastic (COP) method, or an ultrasonic bonding method.

The circuit board PCB may be disposed on the other side opposite to one side of each of the plurality of flexible circuit boards FPCB connected to the display panel DPNL. The circuit board PCB may be electrically connected to the display panel DPNL through the flexible circuit board FPCB and may exchange signals with the driving circuit DIC. The circuit board PCB may provide image data, control signals, power voltage, etc. to the display panel DPNL or the flexible circuit board FPCB. The circuit board PCB may be, but is not limited to, a flexible printed circuit board or a rigid printed circuit board. For example, the circuit board PCB may be a rigid printed circuit board.

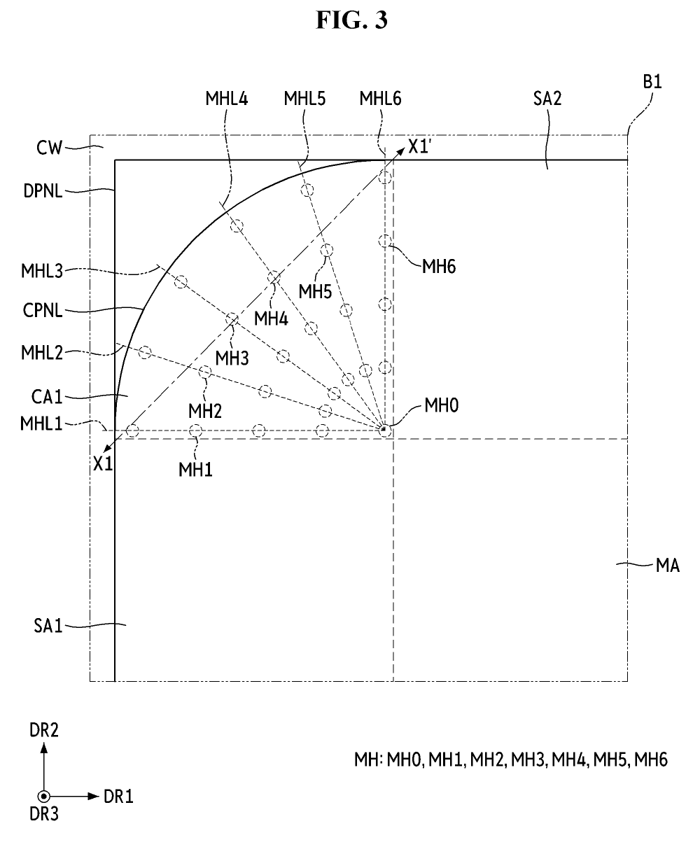

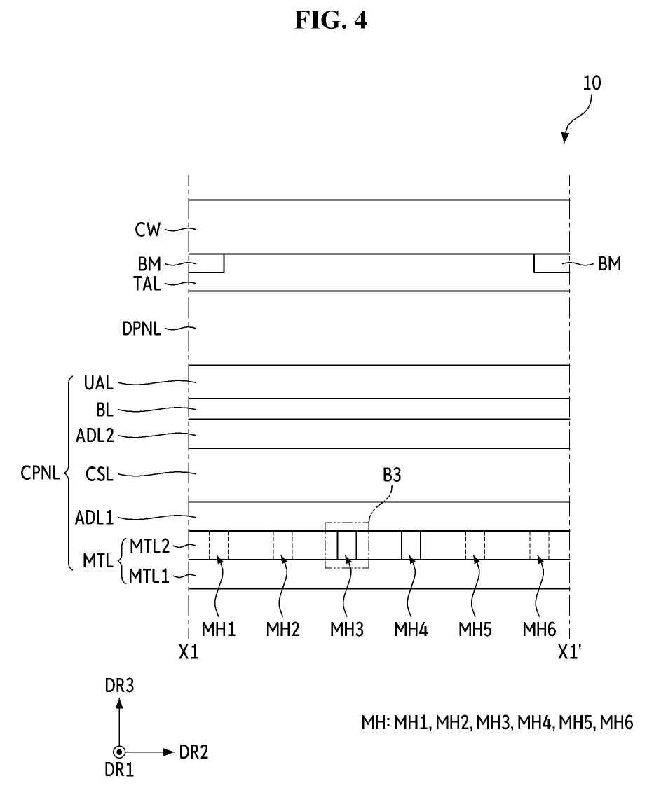

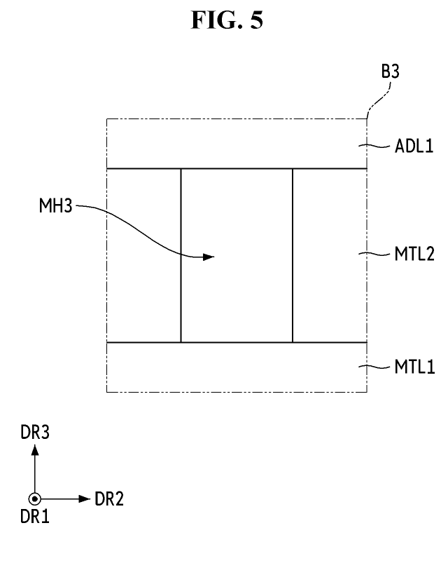

FIG. 3 is an enlarged plan view of portion B1 of FIG. 2. FIG. 4 is a cross-sectional view of the display device of FIG. 3 taken along line X1-X1’. FIG. 5 is an enlarged cross-sectional view of a portion B3 of FIG. 4.

Referring to FIGS. 3 to 5, the display device 10 may further include a light blocking member BM to prevent accessory members disposed in the non-display area NDA from being visually recognized from the outside. The light blocking member BM may be an organic film including a colored or black organic material. The light blocking member BM may be formed to surround a perimeter of the cover window CW on a rear surface of the cover window CW by a coating method. The light blocking member BM may overlap the bezel area BZA of the cover window CW and may partially overlap the non-display area NDA of the display panel DPNL depending on an angle viewed by the user.

The display device 10 may further include a transparent adhesive layer TAL that couples the display panel PDNL and the cover window CW. The transparent adhesive layer TAL may be a transparent adhesive material such as an optical clear adhesive (OCA) or an optical clear resin (OCR).

The cover panel CPNL may include a metal layer MTL, a first adhesive layer ADL1, a cushion layer CSL, a second adhesive layer ADL2, a light blocking layer BL, and an upper adhesive layer UAL.

The metal layer MTL may be positioned below the cover panel CPNL, may discharge heat generated inside the display device 10 to the outside, and may serve to shield electromagnetic waves. The metal layer MTL may include a conductive metal selected from the group consisting of metals such as copper (Cu), silver (Ag), gold (Au), aluminum (Al), nickel (Ni), etc., which have excellent thermal conductivity, or a combination thereof. For example, the metal layer MTL may include a first metal layer MTL1 and a second metal layer MTL2 positioned on the first metal layer MTL1. In the present embodiment, the first metal layer MTL1 may include copper (Cu), and the second metal layer MTL2 may include aluminum (Al). The coefficient of thermal expansion of the first metal layer MTL1 and the coefficient of thermal expansion of the second metal layer MTL2 may be different from each other. In some embodiments, the coefficient of thermal expansion of the second metal layer MTL2 may be greater than the coefficient of thermal expansion of the first metal layer MTL1.

The second metal layer MTL2 may define therein through-holes MH that overlap the corner area CA and penetrate through the second metal layer MTL2, and the through-holes MH may be spaced apart from each other. The through-holes MH of the second metal layer MTL2 may be arranged in various patterns such as a grid, radial, or zigzag pattern. In some embodiments, the through-holes MH may be arranged in a radial pattern. For example, the through-holes MH1, MH2, MH3, MH4, MH5, and MH6 may be arranged in a radial shape along a first through-hole line to a sixth through-hole line MHL1, MHL2, MHL3, MHL4, MHL5, and MHL6 having different inclinations between the first direction DR1 and the second direction DRb with respect to a central through-hole MH0. FIG. 3 illustrates six through-hole lines MHL in which the through-holes MH are formed, but this is merely an example and the number of through-hole lines MHL in which the through-holes MH are formed may vary and is not limited to any one embodiment. As illustrated in FIG. 3, the through-holes MH may include first through-holes MH1 positioned on the first through-hole line MHL1 and spaced apart from each other, second through-holes MH2 positioned on the second through-hole line MHL2 and spaced apart from each other, third through-holes MH3 positioned on the third through-hole line MHL3 and spaced apart from each other, fourth through-holes MH4 positioned on the fourth through-hole line MHL4 and spaced apart from each other, fifth through-holes MH5 positioned on the fifth through-hole line MHL5 and spaced apart from each other, and sixth through-holes MH6 positioned on the sixth through-hole line MHL6 and spaced apart from each other, with respect to the central through-hole MH0. Alternatively, in some embodiments, the through-holes MH may be arranged in a grid pattern. Alternatively, in some embodiments, the through-holes MH may not have a pattern.

The through-holes MH of the second metal layer MTL2 may have a circular shape in a plan view as illustrated in FIG. 3. However, the through-holes MH are not limited thereto, and may have various shapes such as triangles and squares in a plan view. In addition, the through-holes MH may have various sizes within a range that ensures a minimum area capable of performing heat dissipation and shielding functions, and may be arranged spaced apart from adjacent through-holes MH by various intervals.

The through-holes MH may be positioned on the inside of the second metal layer MTL2 and may not be visually recognized from the outside of the cover panel CPNL due to layers disposed on the upper and lower portions of the second metal layer MTL2.

FIGS. 3 to 5 illustrate the through-holes MH formed in an area overlapping the first corner area CA1 of the second metal layer MTL2 as examples, but the through-holes MH may be identically formed in areas overlapping the second to fourth corner areas CA2, CA3, and CA4 of the second metal layer MTL2.

As the second metal layer MTL2 includes the through-holes MH overlapping the corner area CA, a force generated inside the cover panel CPNL due to thermal expansion, etc. and concentrated at the corner may be dispersed. Therefore, a lifting phenomenon of the cover panel CPNL due to thermal expansion that occurs under high temperature and high humidity conditions may be prevented, and thus the reliability of the display device 10 may be improved.

The first adhesive layer ADL1 may be positioned on the second metal layer MTL2. The first adhesive layer ADL1 may be positioned between the metal layer MTL and the cushion layer CSL and may adhere the metal layer MTL and the cushion layer CSL to each other. The first adhesive layer ADL1 may include an optically transparent pressure sensitive adhesive (PSA).

The cushion layer CSL may be positioned on the metal layer MTL. The cushion layer CSL may serve to absorb external impact and prevent the display device 10 from being damaged. The cushion layer CSL may include a single layer or a plurality of stacked films. In some embodiments, the cushion layer CSL may include an elastically deformable material. For example, the cushion layer CSL may include thermoplastic elastomer, polystyrene, polyolefin, polyurethane thermoplastic elastomers, polyamides, synthetic rubbers, polydimethylsiloxane, polybutadiene, polyisobutylene, poly(styrene-butadiene styrene), polyurethane, polychloroprene, polyethylene, silicone, and the like, and a combination thereof, but is not limited thereto, and a suitable material may be selected from materials having elasticity within a range that does not affect an image display of the display panel DPNL.

The second adhesive layer ADL2 may be positioned on the cushion layer CSL. The second adhesive layer ADL2 may be positioned between the cushion layer CSL and the light blocking layer BL and may adhere the cushion layer CSL and the light blocking layer BL to each other. The second adhesive layer ADL2 may include an optically transparent pressure sensitive adhesive (PSA).

The light blocking layer BL may be positioned on the second adhesive layer ADL2. The light blocking layer BL may serve to block the transmission of light and prevent components disposed below the light blocking layer BL from being visually recognized from the outside of the display device 10. The light blocking layer BL may be a colored film including a light blocking material or having low light transmittance. For example, the light blocking layer BL may be a black plastic film, for example, a black polyethylene terephthalate (PET) film.

The upper adhesive layer UAL may be positioned on the light blocking layer BL. The upper adhesive layer UAL may be positioned on the cover panel CPNL and may adhere the cover panel CPNL and the display panel DPNL to each other. The upper adhesive layer UAL may be at least one of an optical clear resin (OCR), an optical clear adhesive (OCA), and a pressure sensitive adhesive (PSA). In an embodiment, the upper adhesive layer UAL may be an embossing adhesive layer. The material of the embossing adhesive layer is not particularly limited, and adhesive materials widely known to those skilled in the art may be used. For example, various polymer resins may be used as the materials for the embossing adhesive layer.

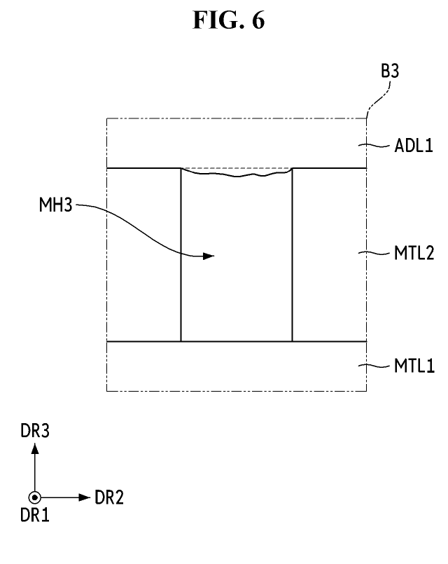

FIGS. 6 to 8 are views illustrating modified examples of the display device of FIG. 5.

Hereinafter, the differences will be mainly described and duplicated descriptions will be omitted.

Referring to FIG. 6, compared to FIG. 5, the first adhesive layer ADL1 may be further positioned inside the through-hole MH of the second metal layer MTL2 and may not be in direct contact with an inner side surface of the second metal layer MTL2 defining the through-hole MH.

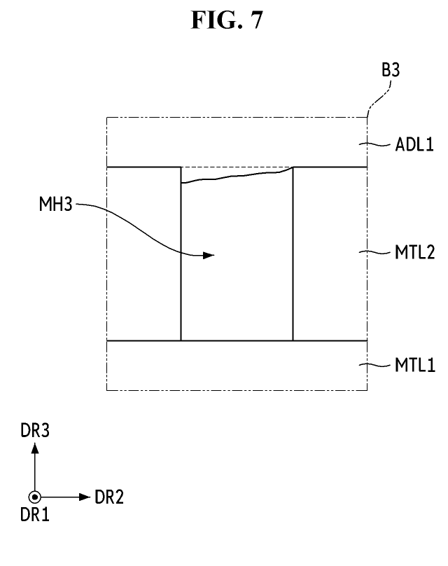

Referring to FIG. 7, compared to FIG. 6, a portion of the first adhesive layer ADL1 positioned inside the through-hole MH may be in direct contact with the inner side surface of the second metal layer MTL2 defining the through-hole MH, and another portion of the first adhesive layer ADL1 positioned inside the through-hole MH may not be in direct contact with the inner side surface of the second metal layer MTL2 defining the through-hole MH.

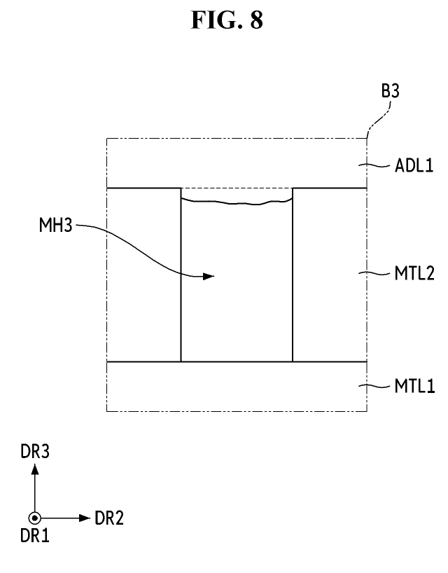

Referring to FIG. 8, compared to FIG. 7, the first adhesive layer ADL1 positioned inside the through-hole MH may be in direct contact with the inner side surface of the second metal layer MTL2 defining the through-hole MH.

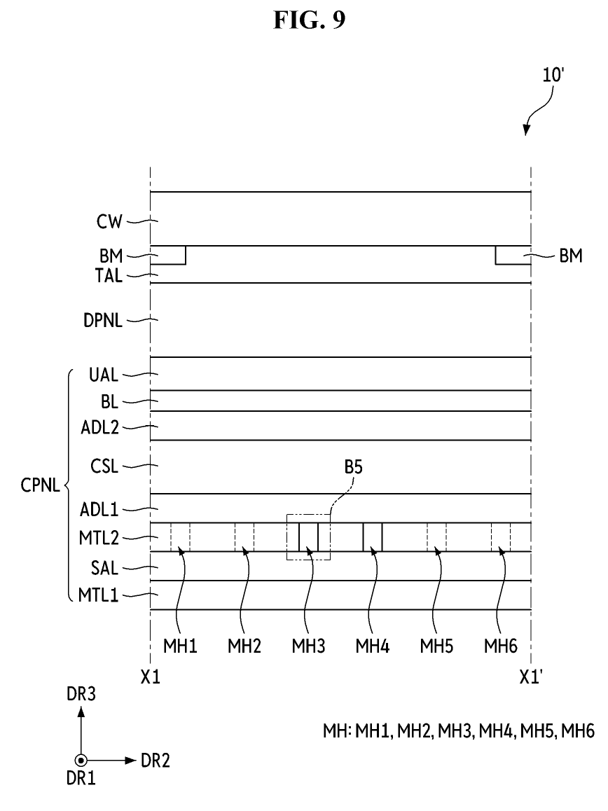

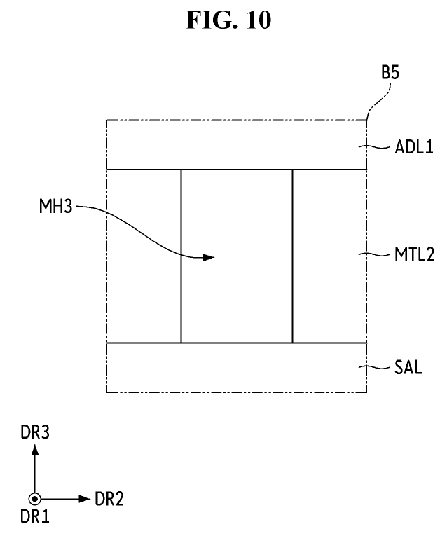

FIG. 9 is a cross-sectional view taken along line X1-X1’ of FIG. 3 of a display device according to another embodiment. FIG. 10 is an enlarged plan view of portion B5 of FIG. 9.

Hereinafter, the differences will be mainly described and duplicated descriptions will be omitted.

Referring to FIGS. 9 and 10, compared to FIGS. 4 and 5, a display device 10’ may further include a lower adhesive layer SAL positioned between the first metal layer MTL1 and the second metal layer MTL2. The lower adhesive layer SAL may adhere the first metal layer MTL1 and the second metal layer MTL2 to each other. The lower adhesive layer SAL may include an optically transparent pressure sensitive adhesive (PSA).

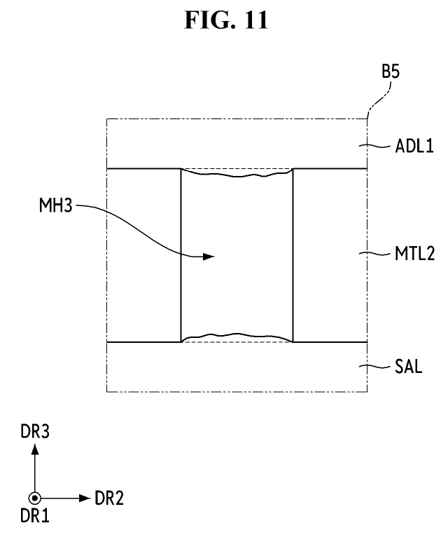

FIGS. 11 to 13 are views illustrating modified examples of the display device of FIG. 10.

Hereinafter, the differences will be mainly described and duplicated descriptions will be omitted.

Referring to FIG. 11, compared to FIG. 10, the first adhesive layer ADL1 and the lower adhesive layer SAL may be further positioned inside the through-hole MH of the second metal layer MTL2 and may not be in direct contact with the inner side surface of the second metal layer MTL2 defining the through-hole MH.

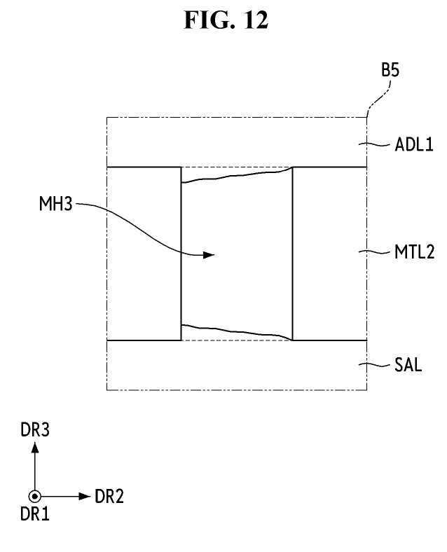

Referring to FIG. 12, compared to FIG. 11, a portion of the first adhesive layer ADL1 and the lower adhesive layer SAL positioned inside the through-hole MH may be in direct contact with the inner side surface of the second metal layer MTL2 defining the through-hole MH of the second metal layer MTL2, and another portion of the first adhesive layer ADL1 and the lower adhesive layer SAL positioned inside the through-hole MH may not be in direct contact with the inner side surface of the second metal layer MTL2 defining the through-hole MH of the second metal layer MTL2.

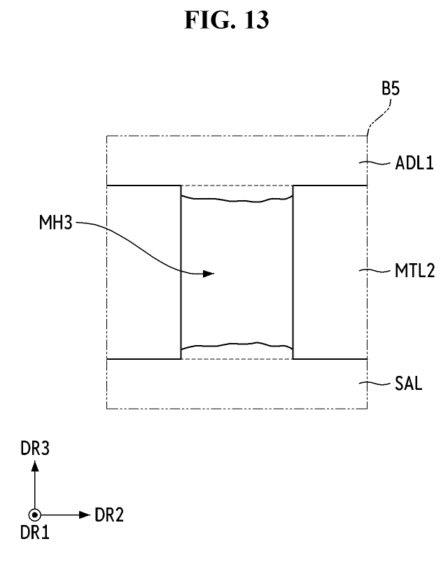

Referring to FIG. 13, compared to FIG. 12, the first adhesive layer ADL1 and the lower adhesive layer SAL positioned inside the through-hole MH may be in direct contact with the inner side surface of the second metal layer MTL2 defining the through-hole MH of the second metal layer MTL2.

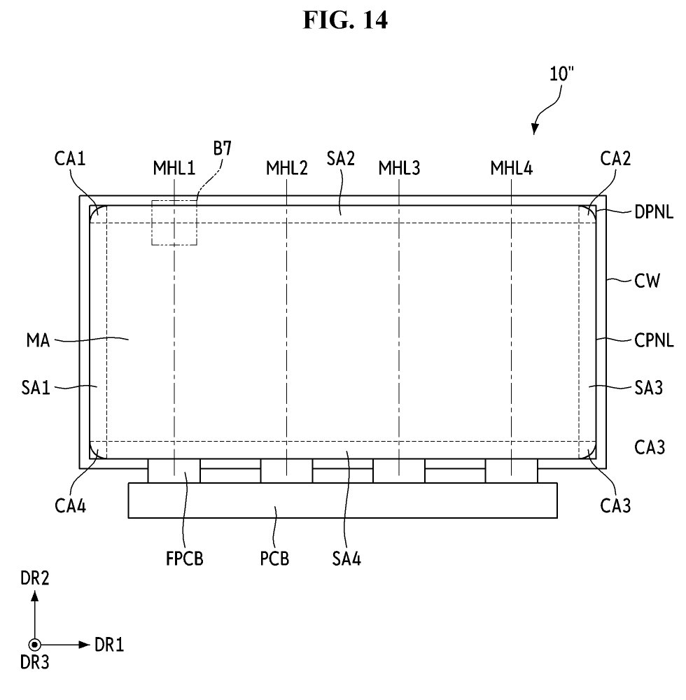

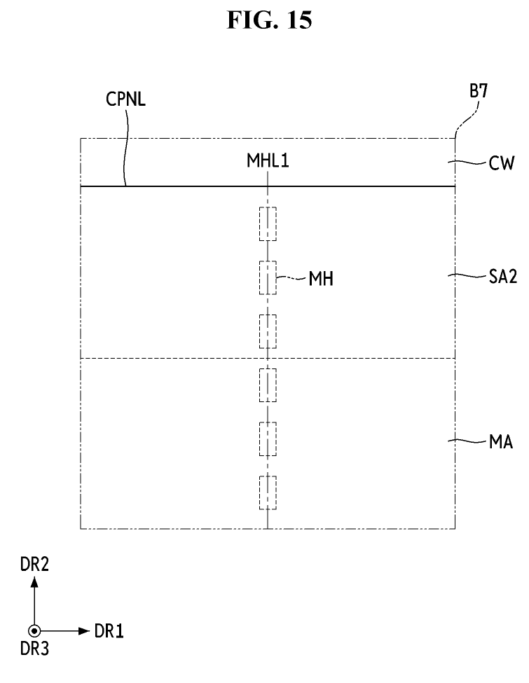

FIG. 14 is a rear view of a display device according to another embodiment. FIG. 15 is an enlarged plan view of portion B7 of FIG. 14.

Hereinafter, the differences will be mainly described and duplicated descriptions will be omitted.

Referring to FIGS. 14 and 15, compared to FIGS. 2 and 3, the second metal layer MTL2 may define therein through-holes MH that overlap the central area MA, the second peripheral area SA2, and the fourth peripheral area SA4 and penetrate through the second metal layer MTL2, and the through-holes MH may be spaced apart from each other. The through-holes MH may be arranged in a grid pattern. For example, the through-holes MH may be arranged in a grid shape along first to fourth through-hole lines MHL1, MHL2, MHL3, and MHL4 spaced apart in the first direction DR1. The through-holes MH may include through-holes MH positioned on the first through-hole line to the fourth through-hole line MHL1, MHL2, MHL3, and MHL4 in the second direction DR2 and spaced apart from each other. FIG. 14 illustrates four through-hole lines MHL in which the through-holes MH are formed, but this is merely an example and the number of through-hole lines MHL in which the through-holes MH are formed may vary and is not limited to any one embodiment.

The through-holes MH of the second metal layer MTL2 may have a quadrangular shape in a plan view as illustrated in FIG. 15. However, the through-holes MH are not limited thereto, and may have various shapes such as triangles and circles in a plan view. In addition, the through-holes MH may have various sizes within a range that ensures a minimum area capable of performing heat dissipation and shielding functions, and may be arranged spaced apart from adjacent through-holes MH by various intervals.

FIGS. 14 and 15 illustrate the through-holes MH formed in the areas overlapping the central area MA, the second peripheral area SA2, and the fourth peripheral area SA4 of the second metal layer MTL2 as an example, but the through-holes MH may be identically formed in one or more of the areas overlapping the central area MA and the first to fourth peripheral areas SA1, SA2, SA3, and SA4 of the second metal layer MTL2.

As the second metal layer MTL2 includes the through-holes MH overlapping the corner area CA, a force generated inside the cover panel CPNL due to thermal expansion, etc. and concentrated at the corner may be dispersed. Therefore, a lifting phenomenon of the cover panel CPNL due to thermal expansion that occurs under high temperature and high humidity conditions may be prevented, and thus the reliability of the display device 10 may be improved.

In addition, the corner area CA of the cover panel CPNL may further define therein an alignment opening ALH positioned at the outermost edge of the cover panel CPNL. Although not directly illustrated in FIG. 14, the alignment opening ALH may be positioned in one or more of the first to fourth corner areas CA1, CA2, CA3, and CA4, and is not limited to any one embodiment.

Although not illustrated, in a display device 10” of FIGS. 14 and 15 according to the embodiment, the display device 10” may have the same structure as FIGS. 4 and 9 described above in cross-sectional view, and the through-holes MH of the second metal layer MTL2 of the display device 10” may have the same arrangement relationship as the layers disposed on the upper and lower portions of the second metal layer MTL2 as illustrated in FIGS. 5 to 8 and FIGS. 10 to 13 described above, and are not limited to any one embodiment.

The display device according to the embodiment may be applied to various electronic devices. The display device according to the embodiment may be applied to various electronic devices.

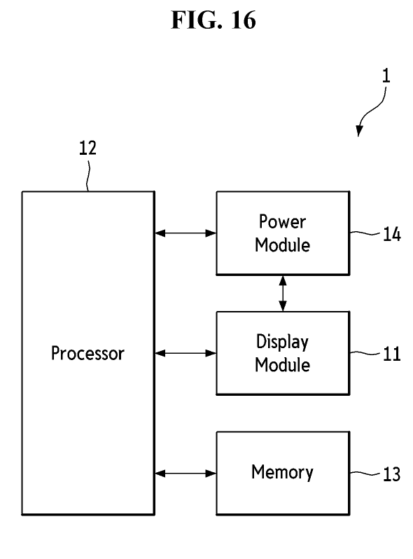

FIG. 16 is a block diagram of an electronic device according to an embodiment.

Referring to FIG. 16, an electronic device 1 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

Data information necessary for an operation of the processor 12 or the display module 11 may be stored in the memory 15. When the processor 12 executes an application stored in the memory 15, image data signals and/or input control signals may be transmitted to the display module 11, and the display module 11 may process the provided signals and output image information through a display screen.

The power module 14 may include a power supply module, such as a power adapter or a battery device, and a power conversion module that converts power supplied by the power supply module to generate power required for an operation of the electronic device 1.

At least one of the components of the electronic device 1 described above may be included in the display device according to the above-described embodiments. In addition, some of the individual modules functionally included within one module may be included within the display device, while others may be provided separately from the display device. For example, the display device includes the display module 11, and the processor 12, the memory 13, and the power module 14 may be provided in the form of other devices within the electronic device 1 other than the display device.

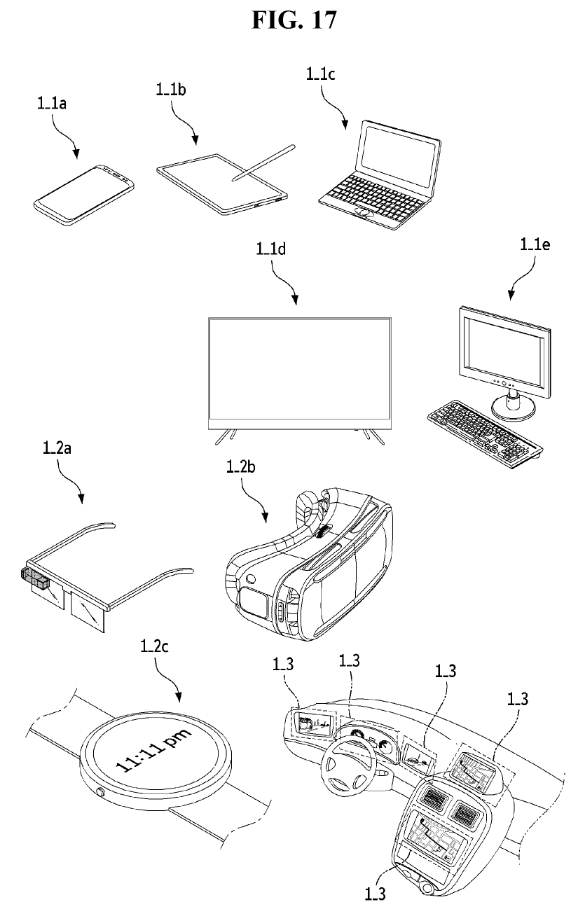

FIG. 17 illustrates schematic diagrams of electronic devices according to various embodiments.

Referring to FIG. 17, various electronic devices to which the display device according to the embodiments is applied may include not only an image display electronic device such as a smart phone 1_1a, a tablet PC 1_1b, a laptop 1_1c, a TV 1_1d, and a desk monitor 1_1e, but also a wearable electronic device including a display module such as a smart glasses 1_2a, a head mounted display 1_2b, a smart watch 1_2c, and the like, and a vehicle electronic device 1_3 including a display module such as a Center Information Display (CID), a room mirror display, etc., disposed on a vehicle’s instrument panel, center fascia, or dashboard.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A display device comprising:
a display panel; and
a cover panel positioned on one surface of the display panel,
wherein the cover panel includes:
a light blocking layer positioned on the one surface of the display panel,
a cushion layer positioned on the light blocking layer,
a first metal layer positioned on the cushion layer, and
a second metal layer positioned on the first metal layer,
wherein in a plan view, the cover panel includes a central area, peripheral areas adjacent to the central area in a first direction and a second direction intersecting the first direction, and corner areas at least partially surrounding the central area and the peripheral areas,
the first metal layer defines therein through-holes, which overlap the corner areas and penetrate through the first metal layer, and
the through-holes are spaced apart from each other.

2. The display device of claim 1, wherein outermost edges of the corner areas of the cover panel include a curve in the plan view.

3. The display device of claim 1, wherein the through-holes are arranged in a radial pattern.

4. The display device of claim 3, wherein the through-holes are not visually recognized from an outside of the cover panel.

5. The display device of claim 1, wherein a coefficient of thermal expansion of the first metal layer and a coefficient of thermal expansion of the second metal layer are different from each other.

6. The display device of claim 5, wherein the coefficient of thermal expansion of the first metal layer is greater than the coefficient of thermal expansion of the second metal layer.

7. The display device of claim 1, further comprising an adhesive layer positioned between the cushion layer and the first metal layer,
wherein the adhesive layer is further positioned inside the through-holes.

8. The display device of claim 7, wherein the adhesive layer is in direct contact with inner side surfaces of the first metal layer defining the through-holes.

9. The display device of claim 1, further comprising a lower adhesive layer positioned between the first metal layer and the second metal layer,
wherein the lower adhesive layer is further positioned inside the through-holes.

10. The display device of claim 9, wherein the lower adhesive layer is in direct contact with inner side surfaces of the first metal layer defining the through-holes.

11. The display device of claim 1, wherein the first metal layer includes aluminum, and the second metal layer includes copper.

12. A display device comprising:
a display panel; and
a cover panel positioned on one surface of the display panel,
wherein the cover panel includes:
a light blocking layer positioned on the one surface of the display panel,
a cushion layer positioned on the light blocking layer,
a first metal layer positioned on the cushion layer, and
a second metal layer positioned on the first metal layer,
wherein in a plan view, the cover panel includes a central area, peripheral areas adjacent to the central area in a first direction and a second direction intersecting the first direction, and corner areas at least partially surrounding the central area and the peripheral areas,
the first metal layer defines therein through-holes, which overlap the central area and the peripheral areas and penetrate through the first metal layer, and the through-holes are spaced apart from each other.

13. The display device of claim 12, wherein outermost edges of the corner areas of the cover panel include a curve in the plan view.

14. The display device of claim 12, wherein a coefficient of thermal expansion of the first metal layer and a coefficient of thermal expansion of the second metal layer are different from each other.

15. The display device of claim 14, wherein the coefficient of thermal expansion of the first metal layer is greater than the coefficient of thermal expansion of the second metal layer.

16. The display device of claim 12, further comprising an adhesive layer positioned between the cushion layer and the first metal layer,
wherein the adhesive layer is further positioned inside the through-holes.

17. The display device of claim 16, wherein the adhesive layer is in direct contact with inner side surfaces of the first metal layer defining the through-holes.

18. The display device of claim 12, further comprising a lower adhesive layer positioned between the first metal layer and the second metal layer,
wherein the lower adhesive layer is further positioned inside the through-holes.

19. The display device of claim 18, wherein the lower adhesive layer is in direct contact with inner side surfaces of the first metal layer defining the through-holes.

20. An electronic device comprising:
a display device for displaying an image; and
a processor for transmitting an image data signal for displaying the image to the display device,
wherein the display device comprises:
a display panel; and
a cover panel positioned on one surface of the display panel,
wherein the cover panel includes:
a light blocking layer positioned on the one surface of the display panel,
a cushion layer positioned on the light blocking layer,
a first metal layer positioned on the cushion layer, and
a second metal layer positioned on the first metal layer,
wherein in a plan view, the cover panel includes a central area, peripheral areas adjacent to the central area in a first direction and a second direction intersecting the first direction, and corner areas at least partially surrounding the central area and the peripheral areas,
the first metal layer defines therein through-holes, which overlap the corner areas and penetrate through the first metal layer, and the through-holes are spaced apart from each other.
